(19) United States
(12) Patent Application Publication
(10) Pub. No.: US 2025/0298280 A1
(43) Pub. Date: Sep. 25, 2025

(54) DISPLAY DEVICE

(71) Applicant: Japan Display Inc., Tokyo (JP)

(72) Inventor: Hitoshi TANAKA, Tokyo (JP)

(73) Assignee: Japan Display Inc., Tokyo (JP)

(21) Appl. No.: 19/082,169

(22) Filed: Mar. 18, 2025

(30) Foreign Application Priority Data
Mar. 19, 2024 (JP) 2024-043750

(51) Int. Cl. G02F 1/1362; G02F 1/1368

(52) U.S. Cl. CPC G02F 1/136286; G02F 1/1368; G02F 2203/01

(57) ABSTRACT

According to one embodiment, in a display device, each of a plurality of switching elements comprises a semiconductor layer, one scanning line on the semiconductor layer, one signal line provided in contact with a first portion of the semiconductor layer, a first insulating layer, a second insulating layer, and a first contact hole provided in the first insulating layer and the second insulating layer, and the one signal line is in contact with the first portion via the first contact hole, and the first contact hole is provided across the plurality of pixels and has a rectangular shape in plan view.

### CROSS-REFERENCE TO RELATED APPLICATION

This application is based upon and claims the benefit of priority from Japanese Patent Application No. 2024-043750, filed Mar. 19, 2024, the entire contents of which are incorporated herein by reference.

### FIELD

Embodiments described herein relate generally to a display device.

### BACKGROUND

Active matrix liquid crystal display devices include scanning lines, signal lines, and pixels (subpixels) each disposed in a respective region where respective ones of the scanning line and respective ones of the signal line intersect each other, on a substrate. The pixels (subpixels) each include a switching element that is driven in response to a video signal supplied from a signal line when selected by the scanning line.

### BRIEF DESCRIPTION OF THE DRAWINGS

FIG. 1 is a plan view showing a configuration of a display device according to Embodiment 1.

FIG. 2 is a cross-sectional view schematically showing a configuration example of the display device of Embodiment 1.

FIG. 3 is a plan view schematically showing a configuration of a display device according to Comparative Example 1.

FIG. 4 is a plan view schematically showing a configuration of the display device according to Comparative Example 1.

FIG. 5 is a cross-sectional schematically showing a configuration of a display device according to Comparative Example 2.

FIG. 6 is a plan view schematically showing a configuration of the display device of Embodiment 1.

FIG. 7 is a plan view schematically showing a configuration of the display device of Embodiment 1.

FIG. 8 is a cross-sectional view showing a cross-sectional configuration of the display device taken along line A1-A2 shown in FIG. 6.

FIG. 9 is a plan view schematically showing another configuration example of the display device of Embodiment 1.

FIG. 10 is a cross-sectional view showing a cross-sectional configuration of the display device taken along line B1-B2 shown in FIG. 9.

FIG. 11 is a plan view schematically showing a configuration example of the display device of Embodiment 2.

FIG. 12 is a plan view showing only a contact hole CH1 of the configuration elements shown in FIG. 11.

FIG. 13 is a plan view showing a display device of Comparative Example 3.

FIG. 14 is a plan view showing only a contact hole CH1 of the configuration elements shown in FIG. 13.

FIG. 15 is a cross-sectional view showing a cross-sectional configuration of the display device taken along line C1-C2 shown in FIG. 9.

FIG. 16 is a cross-sectional view showing a cross-sectional configuration of the display device taken along line D1-D2 shown in FIG. 13.

FIG. 17 is a plan view showing another example of the structure of the display device in Embodiment 2.

FIG. 18 is a cross-sectional view showing the cross-sectional structure of the display device cut by the line E1-E2 shown in FIG. 17.

### DETAILED DESCRIPTION

In general, according to one embodiment, a display device comprises
a first substrate;
a second substrate; and
a liquid crystal layer disposed between the first substrate and the second substrate,
wherein
the first substrate comprises:
a plurality of scanning lines extending along a first direction;
a plurality of signal lines extending along a second direction intersecting the first direction;
a plurality of pixels each provided at an intersection of a respective one of the plurality of scanning lines and a respective one of the plurality of signal lines, and
a plurality of switching elements provided respectively in the plurality of pixels,
each of the plurality of switching elements comprises:
a semiconductor layer;
one scanning line of the plurality of scanning lines provided on the semiconductor layer;
one signal line of the plurality of signal lines, provided in contact with a first portion of the semiconductor layer;
a first insulating layer disposed between a third portion of the semiconductor layer and the one scanning line;
a second insulating layer covering the first insulating layer and the one scanning line; and
a first contact hole provided in the first insulating layer and the second insulating layer, and reaching the first portion of the semiconductor layer, and
the one signal line is in contact with the first portion of the semiconductor layer via the first contact hole, and
the first contact hole is provided across the plurality of pixels and has a rectangular shape in plan view.

According to another embodiment, a display device comprises
a first substrate;
a second substrate; and
a liquid crystal layer disposed between the first substrate and the second substrate,
wherein
the first substrate comprises:
a plurality of scanning lines extending along a first direction;
a plurality of signal lines extending along a second direction intersecting the first direction;
a plurality of pixels each provided at an intersection of a respective one of the plurality of scanning lines and a respective one of the plurality of signal lines, and
a plurality of switching elements provided respectively in the plurality of pixels,
each of the plurality of switching elements comprises:
a semiconductor layer;
one scanning line of the plurality of scanning lines provided on the semiconductor layer;
one signal line of the plurality of signal lines, provided in contact with a first portion of the semiconductor layer;
a first insulating layer disposed between a third portion of the semiconductor layer and the one scanning line;
a second insulating layer covering the first insulating layer and the one scanning line;
a first contact hole provided in the first insulating layer and the second insulating layer, and reaching a first portion of the semiconductor layer;
a third insulating layer provided to cover the second insulating layer, the first portion of the semiconductor layer, and the one signal line; and
a second contact hole provided in the first insulating layer, the second insulating layer, and the third insulating layer, and
the one signal line is in contact with the first portion of the semiconductor layer via the first contact hole, and
the first contact hole is provided across the plurality of pixels so as to pass through the plurality of signal lines, and has a rectangular shape in plan view.

An object of the embodiments is to provide a display device which can suppress leakage of light.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general ones, but rather embodiments that illustrate the same or corresponding special technical features of the invention. The following is a detailed description of one embodiment of a display device with reference to the drawings.

In this embodiment, a first direction X, a second direction Y and a third direction Z are orthogonal to each other, but may intersect at an angle other than 90 degrees. The direction toward the tip of the arrow in the third direction Z is defined as up or above, and the direction opposite to the direction toward the tip of the arrow in the third direction Z is defined as down or below. Note that the first direction X, the second direction Y and the third direction Z may as well be referred to as an X direction, a Y direction and a Z direction, respectively.

With such expressions as “the second member above the first member” and “the second member below the first member”, the second member may be in contact with the first member or may be located away from the first member. In the latter case, a third member may be interposed between the first member and the second member. On the other hand, with such expressions as “the second member on the first member” and “the second member beneath the first member”, the second member is in contact with the first member.

Further, it is assumed that there is an observation position to observe the optical control element on a tip side of the arrow in the third direction Z. Here, viewing from this observation position toward the X-Y plane defined by the first direction X and the second direction Y is referred to as plan view. Viewing a cross-section of the display device in the X-Z plane defined by the first direction X and the third direction Z or in the Y-Z plane defined by the second direction Y and the third direction Z is referred to as cross-sectional view.

### Embodiment 1

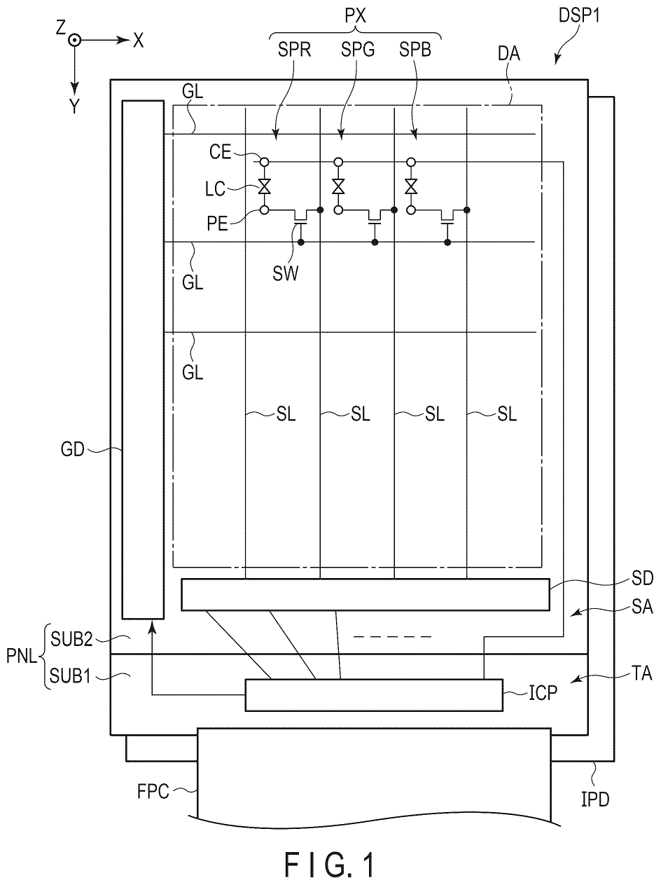

FIG. 1 is a plan view showing a configuration of a display device according to Embodiment 1. A display device DSP1 shown in FIG. 1 comprises a display panel PNL and an illumination device IPD. The display panel PNL comprises a substrate SUB1, a substrate SUB2, and a liquid crystal layer LC. The liquid crystal layer LC is an example of a display functional layer, and is sealed between the substrate SUB1 and the substrate SUB2.

The display panel PNL comprises a display area DA for displaying images and a peripheral area SA surrounding the display area DA in the region where the substrate SUB1 and the substrate SUB2 overlap each other. The display panel PNL comprises a plurality of pixels PX in the display area DA. The plurality of pixels PX are arranged in a matrix pattern.

The substrate SUB1 comprises a plurality of scanning lines GL and a plurality of signal lines SL in the display area DA. The scanning lines GL each extend along the first direction X and are aligned along the second direction Y. The signal lines SL each extend along the second direction Y and are aligned along the first direction X.

The substrate SUB1 has a scanning line drive circuit GD and a signal line drive circuit SD in the peripheral area SA. The scanning lines GL are electrically connected to the scanning line drive circuit GD. The signal lines SL are electrically connected to the signal line drive circuit SD.

The pixels PX each comprises a plurality of subpixels SP. Each of the subpixels SP corresponds to a region compartmentalized by each adjacent pair of scanning lines GL and each adjacent pair of adjacent signal lines SL, for example. Note that in this disclosure, a subpixel SP is, in some cases, simply referred to as a pixel PX. It can be said that each subpixel SP (pixel PX) is disposed in a region where a respective scanning line GL and a respective signal line SL intersect each other.

In the example shown in FIG. 1, one pixel PX comprises three subpixels SPR, SPG, and SPB. The Sub-pixel SPR displays red, subpixel SPG displays green, and subpixel SPB displays blue. Note here that the pixel PX may comprises more subpixels SP. Further, the colors displayed by the subpixels SP are not limited to red, green, and blue, and may be other colors such as white and yellow.

In each of the subpixels SP, the substrate SUB1 comprises a switching element SW and a pixel electrode PE. The switching element SW is electrically connected to the respective scanning line GL and the respective signal line SL. The pixel electrode PE is electrically connected to the switching element SW. The common electrode CE is provided in common for a plurality of subpixels SP. The common electrode CE is provided on the substrate SUB1.

The substrate SUB1 comprises a terminal area TA that does not overlap the substrate SUB2. In the example shown in FIG. 1, an IC chip ICP and a flexible printed circuit board FPC are mounted on the terminal area TA. The IC chip ICP may as well be mounted on the flexible printed circuit board FPC.

For example, the IC chip ICP is electrically connected to the common electrode CE, the scanning line drive circuit GD, and the signal line drive circuit SD. The IC chip ICP supplies a common voltage Vcom to the common electrode CE. The IC chip ICP supplies various signals to the scanning line drive circuit GD and the signal line drive circuit SD. The signal line drive circuit SD supplies image signals to each of the signal lines SL.

The illumination device IPD is provided on a rear surface side of the display panel PNL and illuminates the display area DA. The details of the illumination device IPD are omitted, but the illumination device IPD comprises a flat-plate light guide and a plurality of light sources arranged along an edge surface of the light guide.

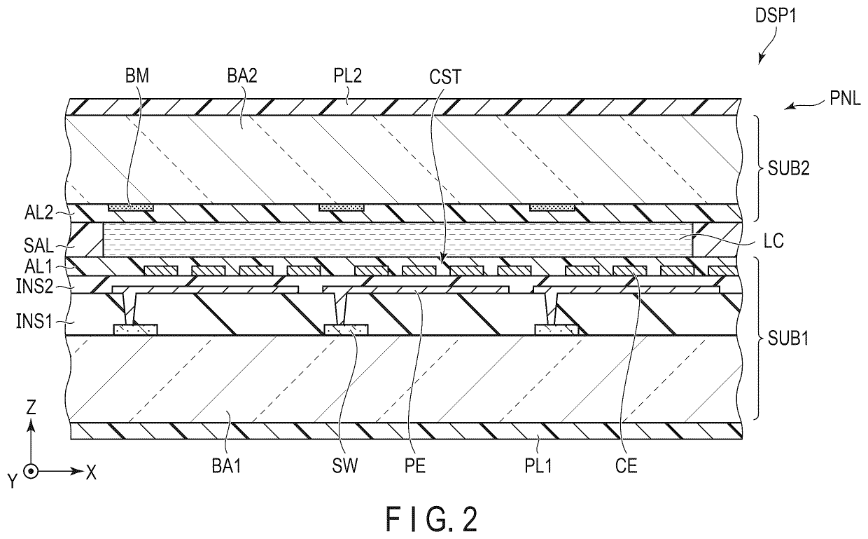

FIG. 2 is a cross-sectional view schematically showing a configuration example of the display device of Embodiment 1. The display device DSP1 shown in FIG. 2 comprises a substrate SUB1, a substrate SUB2, a liquid crystal layer LC, a polarizer PL1, and a polarizer PL2.

The substrate SUB1 comprises a base BA1, switching elements SW, an insulating layer INS1, pixel electrodes PE, an insulating layer INS2, a common electrode CE, and an alignment film AL1. The substrate SUB2 comprises a base BA2, a light-shielding layer BM, and an alignment film AL2.

The substrate SUB1 and the substrate SUB2 are bonded together using a sealant SAL. The liquid crystal layer LC is disposed in the space surrounded by the sealant SAL between the substrate SUB1 and the substrate SUB2.

The base BA1 is formed of a transparent insulating base material, such as glass. The insulating layer INS1 and the insulating layer INS2 are each formed from a single layer of an inorganic insulating material or a single layer of an organic insulating material, or from a stacking multilayer of inorganic insulating material and organic insulating material.

The pixel electrodes PE are provided on the insulating layer INS1. The pixel electrodes PE are connected to the respective switching elements SW via contact holes made in the insulating layer INS1, respectively.

The common electrode CE is formed on the pixel electrodes PE while with the insulating layer INS2 interposed therebetween. Note that the configuration is not limited to that of Embodiment 1. The pixel electrodes PE connected to the switching elements SW may be formed on the common electrode CE with the insulating layer INS2 interposed therebetween. In the electrode formed on the upper side of the pixel electrode PE or the common electrode CE, in the case of Embodiment 1, the common electrode CE, a slit CST is formed, through which electric force lines pass.

The alignment film AL1 is provided to cover the electrode formed on the upper side of the pixel electrode PE or the common electrode CE, in the case of Embodiment 1, the common electrode CE. The alignment film AL1 and the alignment film AL2, which will be described later, should sufficiently be either a horizontal alignment film or a vertical alignment film.

The light shielding layers BM are provided so as to be in contact with the base BA2. The light shielding layers BM oppose the switching elements SW, respectively, along the third direction Z.

The alignment film AL2 is provided to cover the base BA2 and the light shielding layers BM.

The polarizer PL1 is provided in contact with the surface on an opposite side to the surface on which the base BA1 opposes the liquid crystal layer LC. The polarizer PL2 is provided so as to be in contact with the surface on an opposite side to the surface on which the base BA2 opposes the liquid crystal layer LC. As will be described in more detail later, the polarization axes of the polarizer PL1 and the polarizer PL2 are parallel to the first direction X or the second direction, or one of them is parallel to the first direction X and the other is parallel to the second direction Y.

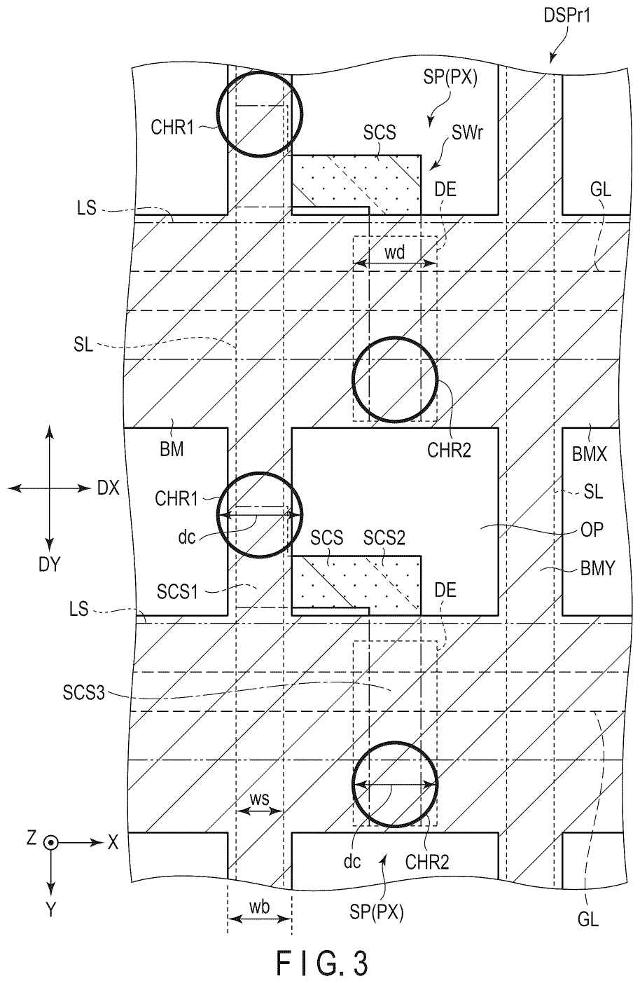

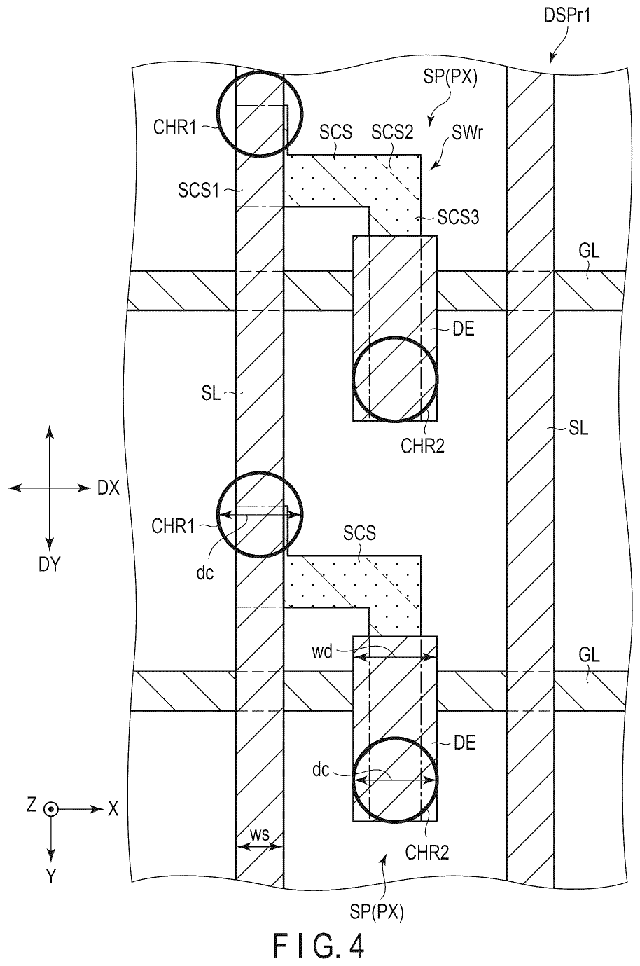

FIGS. 3 and 4 are plan views schematically showing a configuration example of a display device of Comparative Example 1. The display device DSPr1 shown in FIG. 3 comprises scanning lines GL, a light-shielding layer LS, semiconductor layers SCS, signal lines SL, drain electrodes DE, and light-shielding layers BM. FIG. 4 shows a configuration in which the light-shielding layer LS and light-shielding layer BM are excluded from that of FIG. 3.

A pair of scanning lines GL are extended along the first direction X and aligned along the second direction Y. A pair of signal lines SL are extended along the second direction Y and aligned along the first direction X. As described above, the area surrounded by the pair of scanning lines GL and the pair of signal lines SL is a subpixel SP (pixel PX). One subpixel SP (pixel PX) includes one scanning line GL, one signal line SL, and a semiconductor layer SCS.

The light-shielding layers LS are provided so as to overlap the scanning lines GL, respectively, in plan view. The light-shielding layers LS are provided below the scanning lines GL, respectively. The light-shielding layers LS are formed of a conductive material, such as a metal material. The light-shielding layers LS each may be connected to the respective scanning line GL and given the same potential as that of the scanning line GL.

The scanning lines GL, signal lines SL, and light shielding layers LS are formed of, for example, a metal material. As such the metal material, a single layer of titanium (Ti), aluminum (Al), tungsten (W), tantalum (Ta) or the like, or a stacked multilayer of any of these, or a nitride or oxide of any of these metal materials or the like can be used.

The semiconductor layers SCS shown in FIGS. 3 and 4 are each, for example, formed of polycrystalline silicon (poly-Si). The semiconductor layers SCS each comprise a first portion SCS1 that extends along the second direction Y, a second portion SCS2 that extends along the first direction X, and a third portion SCS3 that extends along the second direction Y.

The first portion SCS1 of the semiconductor layer SCS overlaps the respective signal line SL. The third portion SCS3 of the semiconductor layer SCS overlaps the respective drain electrode DE. The second portion SCS2 of the semiconductor layer SCS overlaps an aperture region OP, which will be described later.

The semiconductor layer SCS, the region of the scanning line GL, which overlaps the semiconductor SCS, the region of the signal line SL, which overlaps the semiconductor layer SCS, and the drain electrode DE are used to constitute a switching element SWr. The switching element SWr includes an insulating layer that is not shown in the figure and is provided between the switching element and these components. The switching element SWr is disposed in each of the pixels PX (subpixels SP) provided in the display area DA.

The light shielding layer BM covers part of the light shielding layer LS, the scanning line GL, the signal line SL, the drain electrode DE, and the semiconductor layer SCS. The region of the light shielding layer BM, which covers the scanning line GL and the light shielding layer LS and extends along the first direction X is defined as a light shielding region BMX. The region of the light shielding layer BM, which covers the signal line SL and extends along the second direction Y is defined as a light shielding region BMY.

The region of each subpixel SP, where the light shielding layer BM is not provided is defined as an aperture region OP. The aperture region OP overlaps the second portion SC2 of the semiconductor layer SCS. That is, the second portion SC2 does not overlap the light shielding layer BM.

In the region where the first portion SCS1 of the semiconductor layer SCS and the signal line SL overlap, and the region where the third portion SCS3 of the semiconductor layer SCS and the drain electrode DE overlap, contact holes CHR1 and CHR2 are provided, respectively. The contact holes CHR1 and CHR2 are contact holes made in the insulating layer provided between the semiconductor layer SCS and the signal line SL, and between the semiconductor layer SCS and the drain electrode DE, respectively. The contact hole CHR1 and contact hole CHR2 have a circular shape in plan view. It is assumed here that the contact hole CHR1 and contact hole CHR2 have the same size.

Here, the length (width) of the signal line SL along the first direction X is defined as a length ws. The length (width) of the drain electrode DE along the first direction X is defined as a length wd. The length (width) along the first direction X in the light shielding region BMY, which overlaps the signal line SL and extends along the second direction Y, is defined as a length wb. The diameter of the contact hole CHR1 and contact hole CHR2 is defined as a diameter dc.

As shown in FIGS. 3 and 4, the diameter dc of the contact hole CHR1 and contact hole CHR2 is greater than the length ws of the signal line SL (ws<dc). As shown in FIG. 3, the diameter dc of the contact hole CHR1 is greater than the length wb of the light shielding region BMY (wb<dc). In FIG. 3, the length wd and the diameter dc are approximately the same, but they may be different from each other.

In the high-definition display device DSPr1, it is necessary to make the light shielding layer BM thinner together with the signal line SL in order to obtain a high aperture ratio. It is difficult to reduce the diameter of the contact holes CHR1 and CHR2 in the processing thereof. Therefore, the diameter of the contact hole CHR1 and contact hole CHR2 becomes greater than the width of the signal line SL and the width of the light shielding layer BM. Due to the parts of the contact holes CHR1 and CHR2, which do not overlap the signal line SL and the light shielding layer BM, cancelling of polarization occurs and the contrast is lowered.

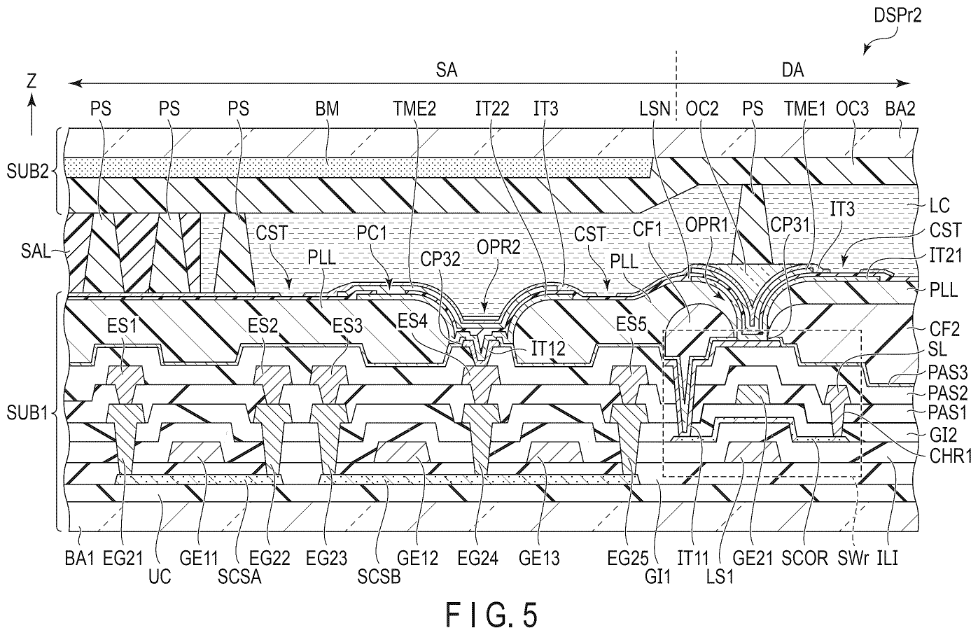

FIG. 5 is a cross-sectional view schematically showing an example of the display device of Comparative Example 2. In the display device DSPr2 shown in FIG. 5, the scanning line drive circuit GD and the signal line drive circuit SD provided in the peripheral area SA are formed by transistors having polycrystalline silicon as the semiconductor layer. On the other hand, the switching elements SWr provided in the display area DA are each formed of a transistor having oxide semiconductor as the semiconductor layer.

The display device DSPr2 shown in FIG. 5 is different from the display device DSPr1 shown in FIG. 3 in that the switching elements SWr are each formed by a transistor having an oxide semiconductor as the semiconductor layer. Further, FIG. 3 shows the configuration of pixels (subpixels SP) in the display area DA, but FIG. 5 shows the configuration of the components as well provided in the display area DA and the peripheral area SA.

On a base BA1, an insulating layer UC is provided. In the peripheral area SA, a semiconductor layer SCSA and a semiconductor layer SCSB are provided on the insulating layer UC. The semiconductor layer SCSA and semiconductor layer SCSB are semiconductor layers formed of polycrystalline silicon.

An insulating layer GI1 is provided to cover the insulating layer UC, the semiconductor layer SCSA, and the semiconductor layer SCSB.

On the semiconductor layer SCSA, a gate electrode GE11 is provided with the insulating layer GI1 interposed therebetween. A gate electrode GE12 and a gate electrode GE13 are provided on semiconductor layer SCSB with the insulating layer GI1 interposed therebetween. The gate electrode GE12 and gate electrode GE13 are disposed to be away from each other at an interval. A light shielding layer LS1 is provided in the display area DA. The gate electrode GE11, the gate electrode GE12, the gate electrode GE13, and the light-shielding layer LS1 are formed of the same material and by the same process. In this specification, those formed by the same material and by the same process are formed in the same layer.

An insulating layer ILI is provided to cover the insulating layer GI1, the gate electrode GE11, the gate electrode GE12, the gate electrode GE13, and the light shielding layer LS1. A semiconductor layer SCOR is provided above the light shielding layer LS1 with the insulating layer ILI interposed therebetween.

An insulating layer GI2 is provided to cover the insulating layer ILI and the semiconductor layer SCOR. An electrode EG21, an electrode EG22, an electrode EG23, an electrode EG24, an electrode EG25, and a gate electrode GE21 are provided on the insulating layer GI2.

The electrode EG21 and the electrode EG22 are in contact with the semiconductor layer SCSB via contact holes made in the insulating layer GI1, insulating layer ILI, and insulating layer GI2. The electrode EG23, the electrode EG24, and the electrode EG25 are in contact with the semiconductor layer SCSB via contact holes made in the insulating layer GI1, insulating layer ILI, and insulating layer GI2. The electrode EG24 is provided between the gate electrode GE12 and the gate electrode GE13. A gate electrode GE21 is provided on the semiconductor layer SCOR with the insulating layer GI2 interposed therebetween.

An insulating layer PAS1 is provided to cover the insulating layer GI2, the electrode EG21, the electrode EG22, the electrode EG23, the electrode EG24, the electrode EG25, and the gate electrode GE21.

An electrode ES1, an electrode ES2, an electrode ES3, an electrode ES4, an electrode ES5, and signal lines SL are provided on the insulating layer PAS1.

The electrode ES1 is connected to the electrode EG21 via a contact hole made in the insulating layer PAS1. The electrode ES2 is connected to the electrode EG22 via a contact hole made in the insulating layer PAS1. The electrode ES3 is connected to the electrode EG23 via a contact hole made in the insulating layer PAS1. The electrode ES4 is connected to the electrode EG24 via a contact hole made in the insulating layer PAS1. The electrode ES5 is connected to the electrode EG25 via a contact hole made in the insulating layer PAS1.

A respective signal line SL is connected to the semiconductor layer SCOR via the contact hole CHR1 made in the insulating layer GI2 and insulating layer PAS1.

An insulating layer PAS2 is provided to cover the insulating layer PAS1, the electrode ES1, the electrode ES2, the electrode ES3, the electrode ES4, the electrode ES5, and the signal line SL.

An electrode IT11 and an electrode IT12 are provided on the insulating layer PAS2. The electrode IT11 and the electrode IT12 are formed of a transparent conductive material, such as indium tin oxide (ITO) or indium zinc oxide (IZO).

The electrode IT11 is connected to the semiconductor layer SCOR via contact holes made in the insulating layer GI2, insulating layer PAS1, and insulating layer PAS2. The electrode IT11 extends over to the gate electrode GE21 on the insulating layer PAS2.

Here, the semiconductor layer SCOR, the insulating layer GI2, the gate electrode GE21, the insulating layer PAS1, the signal line SL, and the electrode IT11 constitute a switching element SWr. Further, when the same voltage as that of the gate electrode GE21 is applied to the light shielding layer LS1, the light shielding layer LS1 and the insulating layer ILI may be included in the switching element SWr. The switching element SWr is provided in each of the pixels (subpixels) disposed in the display area DA.

The electrode IT12 is connected to the electrode ES4 via a contact hole made in the insulating layer PAS2.

An insulating layer PAS3 is provided to cover part of the insulating layer PAS2, the electrode IT11, and the electrode IT12. In the insulating layer PAS3 on the gate electrode GE21, a contact hole CP31 is formed. The insulating layer PAS3 on the electrode ES4 and the electrode IT12 is removed, and a contact hole CP32 is formed.

A color filter CF1 and a color filter CF2 are provided on the insulating layer PAS3. The color filter CF1 and the color filter CF2 are of colors of different from each other.

The color filter CF1 is provided from the left side of the contact hole CP31 on the page over to the electrode IT11. The color filter CF2 is provided from the right side of the contact hole CP31 on the page over to the signal line SL.

The insulation layer PLL is provided to cover the insulation layer PAS3, the color filter CF1, and the color filter CF2. Note here that the insulating layer PLL is not provided over the contact hole CP31 and the contact hole CP32, and an aperture region OPR1 and an aperture region OPR2 of the insulating layer PLL are formed. The insulating layer PLL is formed of, for example, an organic resin material, such as polyimide resin or acrylic resin.

An electrode IT21 and an electrode IT22 are provided on the insulating layer PLL. The electrode IT21 and electrode IT22 are formed of the transparent conductive material described above. The electrode IT21 is connected to the electrode IT11 via the contact hole CP31 and the aperture region OPR1. The electrode IT11 corresponds to a drain electrode DE. The electrode IT21 corresponds to a pixel electrode PE. The electrode IT22 is connected to the electrode IT12 via the contact hole CP32 and the aperture region OPR2.

An insulating layer LSN is provided to cover the insulating layer PLL, electrode IT21, and electrode IT22. It suffices if the insulating layer LSN is formed of an inorganic insulating material, more specifically, silicon oxide or silicon nitride. A contact hole PC1 is formed in the insulating layer LSN above the gate electrode GE12.

An electrode TME1 and an electrode TME2 are provided on the insulating layer LSN. The electrode TME1 and electrode TME2 are formed of a metal material. The electrode TME1 is provided on the electrode IT21 with the insulating layer LSN interposed therebetween. The electrode TME2 is provided on the electrode IT22 with the insulating layer LSN interposed therebetween, and is connected to the electrode IT22 via the contact hole PC1.

An electrode IT3 is provided to cover the insulating layer LSN, the electrode TME1, and the electrode TME2. The electrode IT3 is formed of the transparent conductive material described above. The electrode IT3 has a plurality of slits CST. The electrode IT3 corresponds to the common electrode CE. The electrode TME1 is a supplementary electrode of the common electrode CE (electrode IT3).

An insulating layer OC2 is provided on the electrode IT3 to fill in recesses caused by the aperture region OPR1. It suffices if the insulating layer OC2 is formed of the above-mentioned organic resin material. The insulating layer OC2 planarizes the surface that is above the gate electrode GE21 and in contact with the liquid crystal layer LC.

The common electrode CE (electrode IT3) and the insulating layer OC2 are covered with the alignment film that is not shown in the figure. A spacer PS is provided on the alignment film and on the surface that is planarized by the insulating layer OC2. Further, a spacer PS is provided on the alignment film and above the semiconductor layer SCSA.

The configuration from the base BA1 to the alignment film is the cross-sectional configuration of the substrate SUB1.

A light shielding layer BM is provided in the region that overlaps the peripheral region SA and is in contact with the base BA2. An insulating layer OC3 is provided in contact with the base BA2 and the light shielding layer BM. It suffices if the insulating layer OC3 is formed from the organic insulating material mentioned above. An alignment film not shown in the figure is provided to cover the insulating layer OC3.

The construction from the base BA2 to the alignment film is the cross-sectional configuration of the substrate SUB2.

The spacer PS, the sealant SAL, and the liquid crystal layer LC described above are provided between the substrate SUB1 and the substrate SUB2. The sealant SAL is provided in the peripheral area SA. The spacer PS has the function of maintaining the gap between the substrate SUB1 and the substrate SUB2.

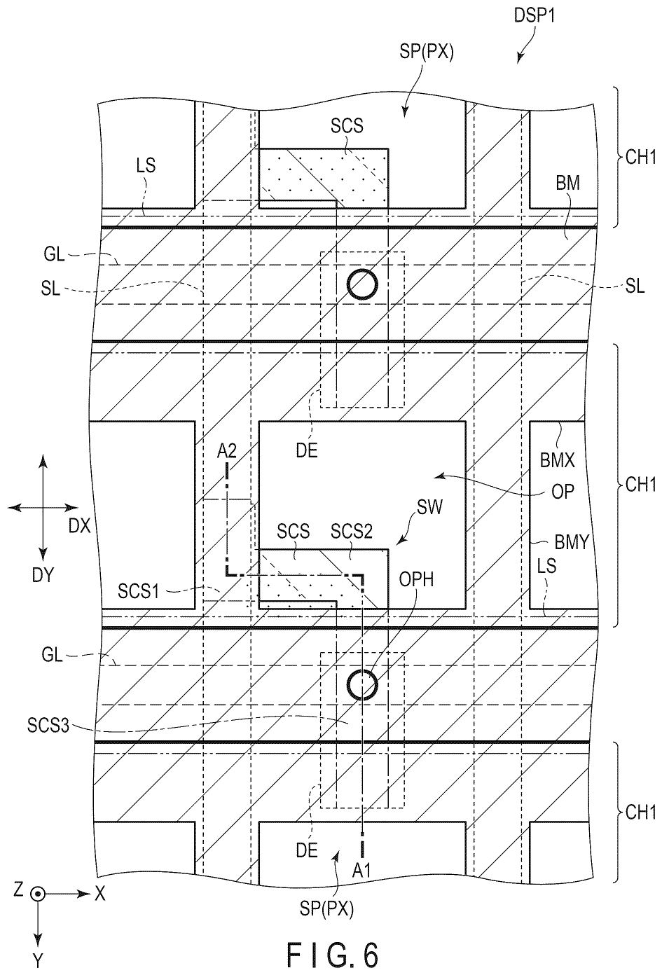

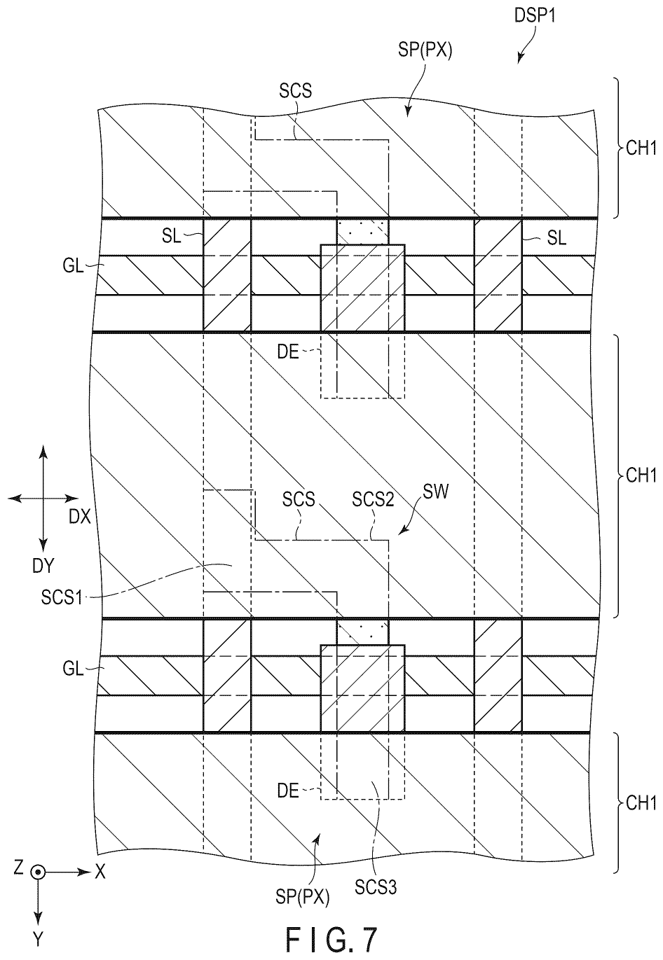

FIGS. 6 and 7 are each a plan view schematically showing a configuration example of the display device of Embodiment 1. The display device DSP1 shown in FIG. 6 is different as compared to the display device DSPr1 shown in FIG. 3 in that the contact hole CH1 has a rectangular shape that is elongated along the first direction X, rather than a circular shape in plan view (contact holes CHR1 and CHR2 shown in FIG. 3). FIG. 7 shows the configuration in which the light shielding layer LS and the light shielding layer BM are removed from that shown in FIG. 6.

The display device DSP1 shown in FIG. 6 comprising scanning lines GL, a light-shielding layer LS, semiconductor layers SCS, signal lines SL, a drain electrode DE, and a light-shielding layer BM. One subpixel SP (pixel PX) includes one scanning line GL, one signal line SL, and a semiconductor layer SCS.

The light shielding layer LS is provided so as to overlap the scanning lines GL in plan view. The light shielding layer LS is provided below the scanning lines GL.

The semiconductor layer SCS included in the display device DSP1 of FIG. 6 is formed, for example, of polycrystalline silicon (poly-silicon). As in the case shown in FIG. 3, the semiconductor layer SCS comprises a first portion SCS1 that extends along the second direction Y, a second portion SCS2 that extends along the first direction X, and a third portion SCS3 that extends along the second direction Y.

The first portion SCS1 of the semiconductor layer SCS overlaps the respective signal line SL. The third portion SCS3 of the semiconductor layer SCS overlaps the respective drain electrode DE.

The light shielding layer BM covers part of the light shielding layer LS, the scanning line GL, the signal line SL, the drain electrode DE, and the semiconductor layer SCS. Of the light shielding layer BM, the light shielding region BMX covers the scanning line GL and the light shielding layer LS. Of the light shielding layer BM, the light shielding region BMY covers the signal line SL.

Of each of the subpixels SP, the aperture region OP, in which the light-shielding layer BM is not provided, overlaps the second portion SCS2 of the semiconductor layer SCS. In other words, the second portion SCS2 does not overlap the light-shielding layer BM.

In FIG. 6, an aperture region OPH is provided so as to overlap the third portion SCS3 of the semiconductor layer SCS and the drain electrode DE. As will be described in more detail later, the aperture region OPH is a contact hole for the drain electrode DE to be in contact with the semiconductor layer SCS (third portion SCS3).

The contact hole CH1 is provided for connecting the signal line SL to the semiconductor layer SCS. The contact hole CH1 overlaps a part of the third portion SCS3 of the semiconductor layer SCS, a part of the drain electrode DE, a part of the signal line SL, and the first portion SCS1 and second portion SCS2 of the semiconductor layer SCS. The contact hole CH1 overlaps the aperture region OP of the light shielding layer BM.

The polarization axes of the polarizer PL1 and polarizer PL2 include, for example, one polarization axis DX parallel to the first direction X and the other polarization axis DY parallel to the second direction Y. The direction of extension of the contact hole CH1 shown in FIGS. 6 and 7 is parallel to the polarization axis DX.

If the direction of extension of the contact hole CH1 is parallel to the polarization axis DX or polarization axis DY, there is no polarization cancellation caused by the contact hole CH1. Therefore, it is possible to improve the contrast of the display device DSP1.

The contact hole CH1 overlaps the entire opening region OP of the light shielding layer BM. The end portion of the contact hole CH1 overlaps the light shielding layer LS. As described above, the contact hole CH1 extends parallel to the polarization axis DX. Note here that the direction of extension of the contact hole CH1 may be parallel to the polarization axis DY.

Further, the contact hole CH1 is provided not only in a single subpixel SP, but provided over multiple subpixels SP disposed adjacent to each other along the first direction X.

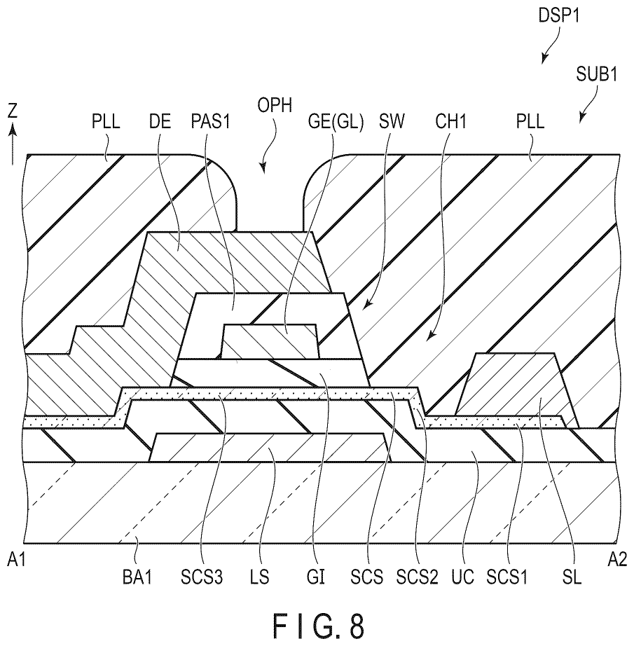

FIG. 8 is a cross-sectional view showing the cross-sectional configuration of the display device taken along the line A1-A2 shown in FIG. 6. FIG. 8 is a cross-sectional view showing the thin film transistor (TFT), which is the switching element SW and its surroundings.

In this disclosure, the thin film transistor, which is the switching element SW, comprises a semiconductor layer formed of polycrystalline silicon-containing silicon or a semiconductor layer formed of an oxide semiconductor, a gate electrode, a signal line SL or a source electrode that is a part of the signal line SL, a drain electrode, an insulating layer (gate insulating layer) provided between the semiconductor layer and the gate electrode, and an insulating layer provided between the semiconductor layer, and, the signal line SL (source electrode) and drain electrode. In this disclosure, it is assumed that the switching element SW is a thin film transistor that includes such components.

The light shielding layer LS is provided on the base BA1. The insulating layer UC is provided to cover the base BA1 and the light shielding layer LS. The semiconductor layer SCS is provided on the insulating layer UC. The semiconductor layer SCS is located to oppose the light-shielding layer LS with the insulating layer UC interposed therebetween. In particular, the third portion SCS3 of the semiconductor layer SCS is located to oppose the light shielding layer LS along the third direction Z.

The drain electrode DE is provided in contact with the third portion SCS3 of the semiconductor layer SCS. The signal line SL is provided in contact with the first portion SCS1 of the semiconductor layer SCS. An insulating layer GI is provided in the region where the third portion SCS3 of the semiconductor layer SCS intersects the light shielding layer LS and the scanning line GL.

A gate electrode GE, which is a part of the scanning line GL, is provided on the insulating layer GI. The insulating layer PAS1 is provided to cover the insulating layer GI and the gate electrode GE. A drain electrode DE is provided on the insulating layer PAS1. The drain electrode DE extends from the region on the insulating layer PAS1 and through the side surface of the insulating layer PAS1 and the side surface of the insulating layer GI, and brought into contact with the third portion SCS3 of the semiconductor layer SCS as described above.

An insulating layer PLL is provided to cover the insulating layer UC, the drain electrodes DE, the semiconductor layer SCS, the insulating layer GI, the insulating layer PAS1, and the signal lines SL. The insulating layer PLL has an aperture region OPH that reaches the drain electrode DE over the semiconductor layer SCS and gate electrode GE.

Between the signal line SL and the drain electrode DE, the contact hole CH1 is made in the insulating layer GI and the insulating layer PAS1, which reaches the semiconductor layer SCS. That is, the signal line SL is in contact with the first portion SCS1 of the semiconductor layer SCS via the contact hole CH1 made in the insulating layer GI and the insulating layer PAS1.

In the display device DSP1 of Embodiment 1, the contact hole CH1 extends in a direction parallel to the polarization axis DX (or polarization axis DY). With this configuration, the cancellation of polarization, which is caused by the contact hole CH1, does not occur and thus it is possible to improve the contrast of the display device DSP1.

### Embodiment 2

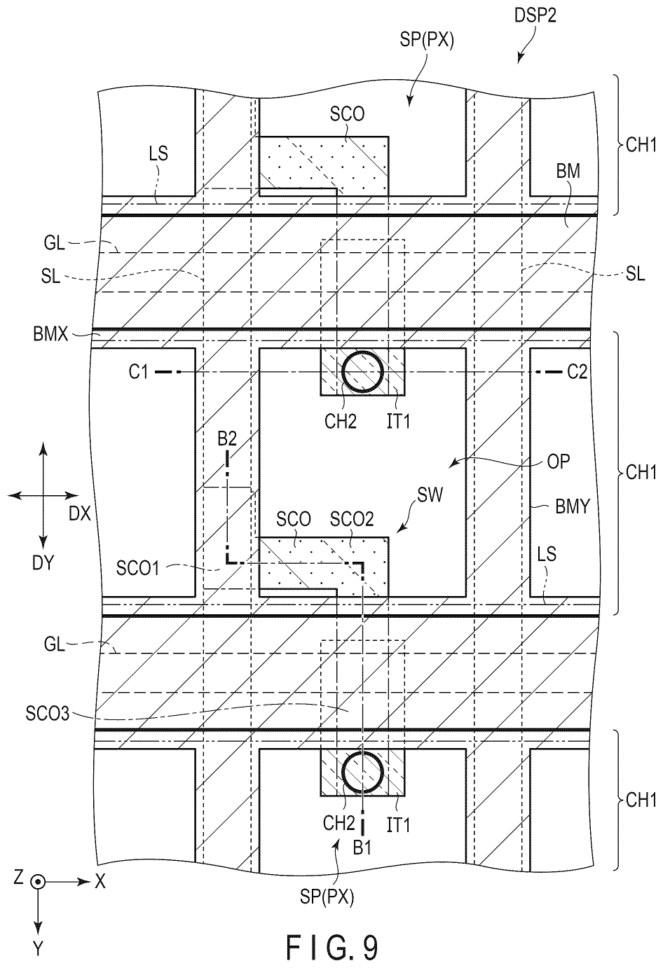

FIG. 9 is a plan view showing another configuration example of a display device in Embodiment 2. The configuration example shown in FIG. 9 is different from the configuration example shown in FIG. 6 in that the semiconductor layer is an oxide semiconductor layer.

A display device DSP2 shown in FIG. 9 includes a semiconductor layer SCO, which is an oxide semiconductor layer. The semiconductor layer SCO comprises a first portion SCO1 that extends along the second direction Y, a second portion SCO2 that extends along the first direction X, and a third portion SCO3 that extends along the second direction Y.

The first portion SCO1 of the semiconductor layer SCO overlaps a respective signal line SL. The third portion SCO3 of the semiconductor layer SCO overlaps an electrode IT1. The electrode IT1 is connected to the third portion SCO3 via the contact hole CH2.

The electrode IT1 is formed, for example, of a transparent conductive material, such as indium tin oxide (ITO), indium zinc oxide (IZZ) or the like. The contact hole CH2 does not overlap the light shielding layer BM. That is, the contact hole CH2 is located within the aperture region OP.

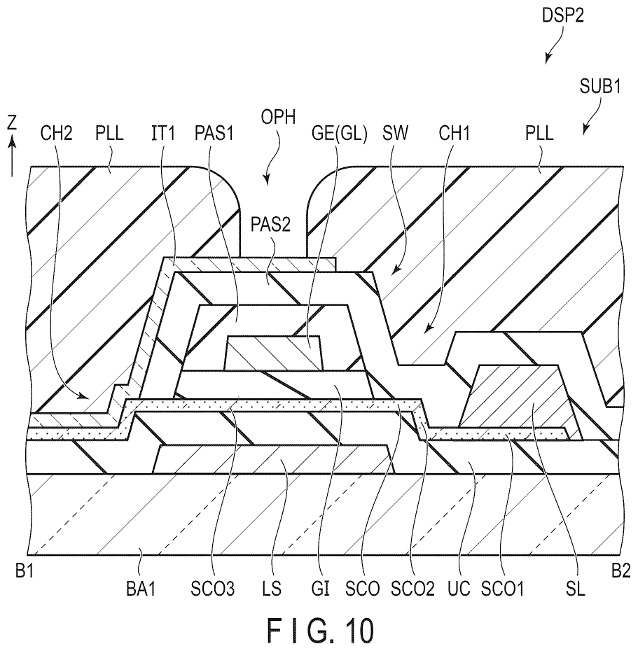

FIG. 10 is a cross-sectional view showing the cross-sectional structure of the display device taken along the line B1-B2 shown in FIG. 9. In the display device DSP2 shown in FIG. 9, the configuration from the base BA1 up to the insulating layer PAS1 is similar to that of the display device DSP2 shown in FIG. 8. Note that the semiconductor layer is a semiconductor layer SCO, which is an oxide semiconductor layer.

In the insulating layer PAS1 and the insulating layer GI, the contact hole CH1 is provided as in the case shown in FIG. 8. The signal line SL is in contact with the first portion SCO1 of the semiconductor layer SCO via the contact hole CH1 made in the insulating layer GI and the insulating layer PAS1.

An insulating layer PAS2 is provided to cover the insulating layer PAS1, the first portion SCO1 of the semiconductor layer SCO, the second portion SCO2, the signal line SL, and the insulating layer UC. The insulating layer GI, the insulating layer PAS1, and the insulating layer PAS2 have a contact hole CH2 that reaches the third portion SCO3 of the semiconductor layer SCO. Further, the insulating layer PAS2 covers the contact hole CH1.

An electrode IT1 is provided on the insulating layer PAS2. The electrode IT1 extends from the region on the insulating layer PAS2 through the side surface of the insulating layer PAS2, and is brought into contact with the third portion SCS3 of the semiconductor layer SCS via the contact hole CH2.

An insulating layer PLL is provided to cover the electrode IT1 and the insulating layer PAS2. In the insulating layer PLL, an aperture region OPH is provided over the semiconductor layer SCO and the gate electrode GE, so as to reach the electrode IT1. The aperture region OPH corresponds to the aperture region OPR1 shown in FIG. 5.

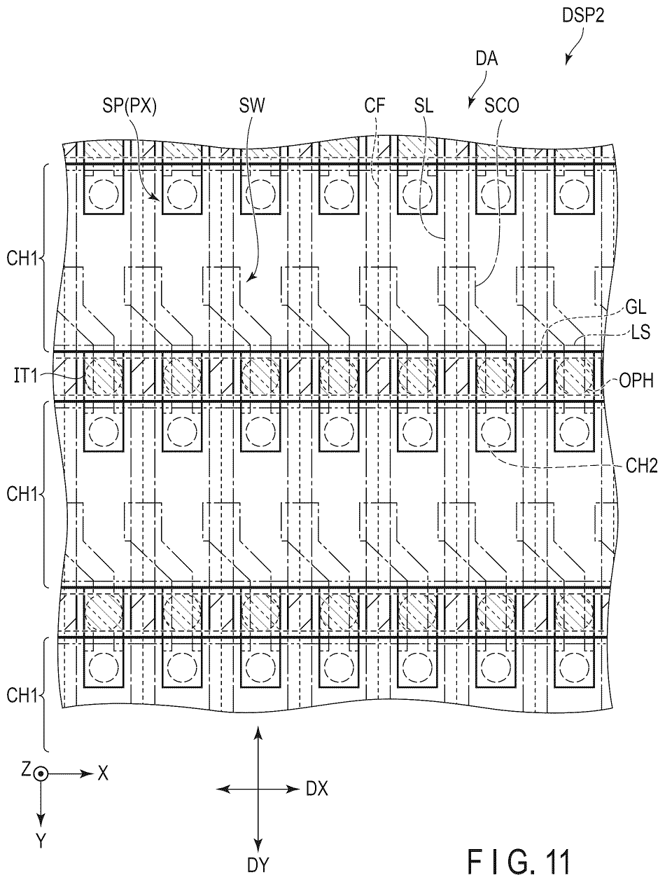

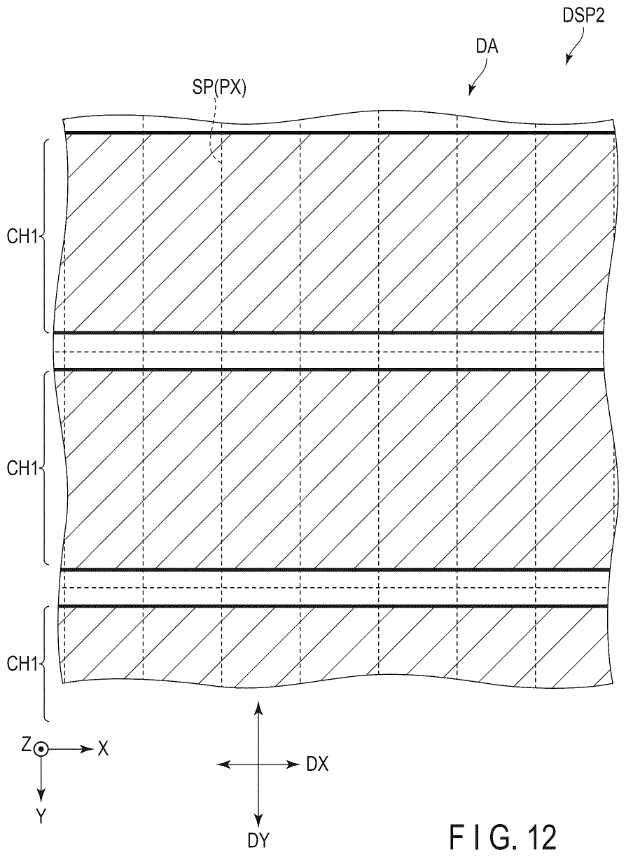

FIG. 11 is a plan view schematically showing a configuration example of the display device of Embodiment 2. FIG. 12 is a plan view showing only contact holes CH1 among the structural components shown in FIG. 11. In FIG. 11, subpixels SP (pixels PX) in the display area DA are arranged in a matrix along the first direction X and the second direction Y. A color filter CF is provided for each subpixel SP (pixel PX). For example, the color filters CF are formed on the substrate SUB2.

As shown in FIGS. 11 and 12, the contact holes CH1 are each provided over multiple subpixels SP. In the display area DA in its entirely, the contact holes CH1 each have a rectangular shape formed along the first direction X.

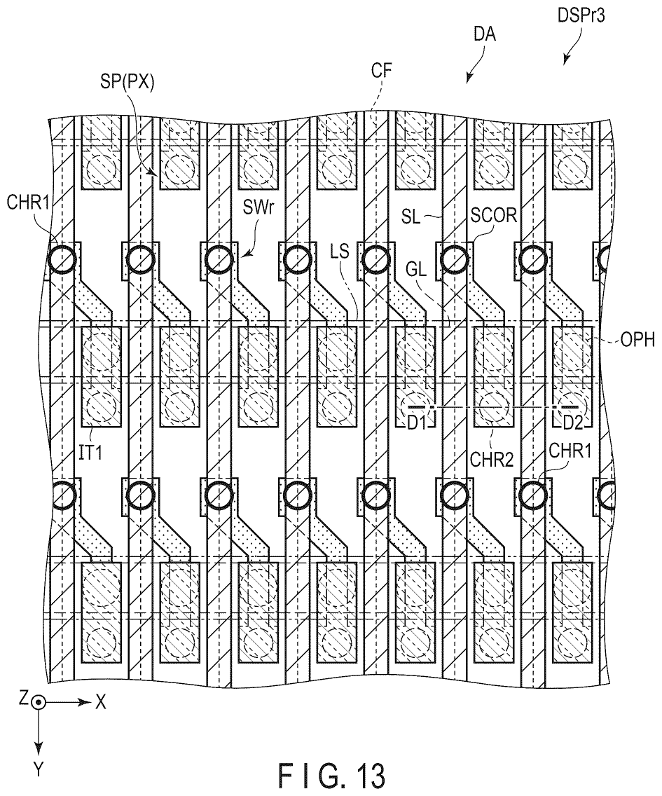

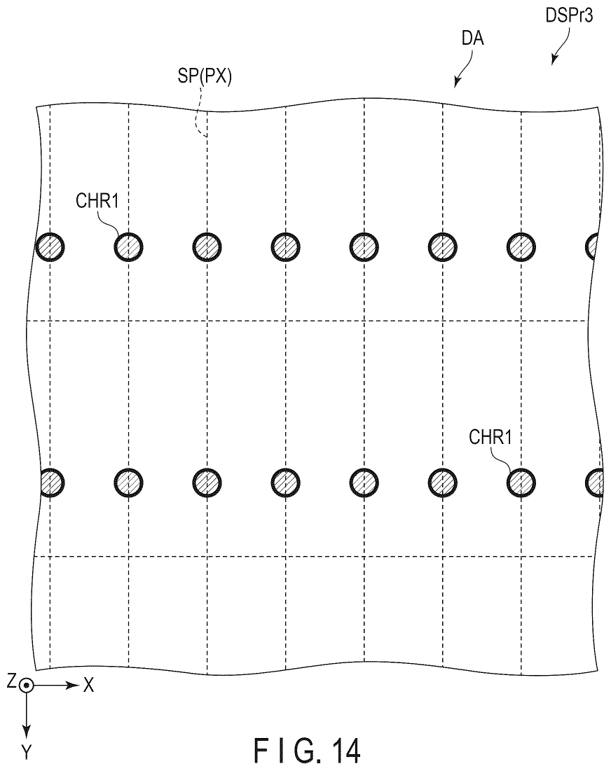

FIG. 13 is a plan view showing a display device of Comparative Example 3. FIG. 14 is a plan view showing only contact holes CH1 among the structural components shown in FIG. 13. In FIG. 13, subpixels SP (pixels PX) in the display area DA are arranged in a matrix along the first direction X and the second direction Y as in the case shown in FIG. 11. A switching element SWr and a color filter CF are provided for each subpixel SP (pixel PX).

As shown in FIGS. 13 and 14, the contact holes CHR1 are each provided to overlap the semiconductor layer SCO in each respective one of the plurality of subpixels SP. The contact holes CHR1 are each provided at the boundary between each respective adjacent pair of subpixels SP, but it can be said that one contact hole CHR1 is provided for each of the subpixels SP.

In the display device DSPr3 shown in FIGS. 13 and 14, the cancellation of polarization occurs due to the part of the contact hole CHR1 that does not overlap the signal line SL or the like, as in the case of the display device DSPr1 shown in FIGS. 3 and 4, and thus degradation in contrast occurs.

In the display device DSP2 of Embodiment 2, the direction of extension of the contact hole CH1 is parallel to the polarization axis DX or polarization axis DY. With this configuration, the cancellation of polarization due to the contact hole CH1 does not occur. Therefore, it is possible to improve the contrast of the display device DSP2.

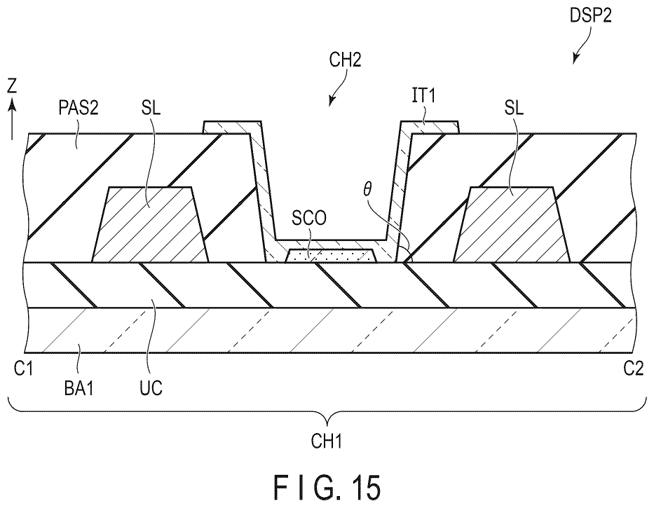

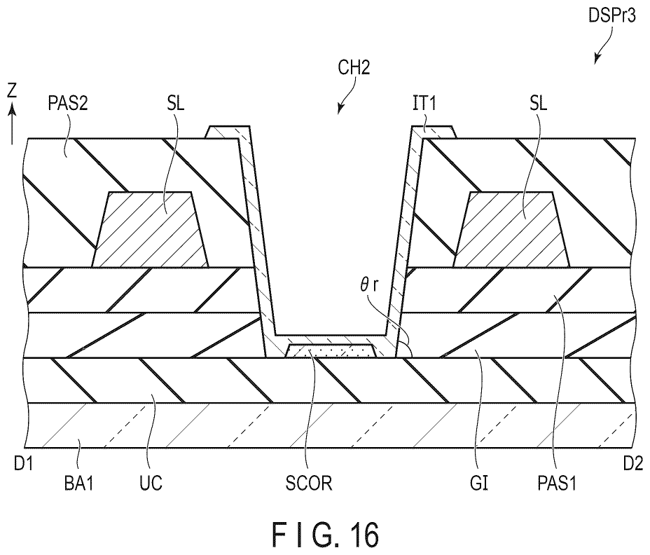

Further, the display device DSP2 of embodiment 2 has an advantageous point in that the taper angle of the sidewall of each contact hole CH2 is smaller than that of Comparative Example 3. FIG. 15 is a cross-sectional view showing the cross-sectional configuration of the display device taken along the line C1-C2 shown in FIG. 9. FIG. 16 is a cross-sectional view showing the cross-sectional configuration of the display device taken along the line D1-D2 shown in FIG. 13.

The display device DSP2 shown in FIG. 15 comprises a base BA1, an insulating layer UC, a semiconductor layer SCO, signal lines SL, an insulating layer PAS2, and an electrode IT1. The base BA1, the insulating layer UC, and the insulating layer PAS2 are stacked into a multilayer in this order along the third direction Z. The signal lines SL are provided on the insulating layer UC by the contact hole CH1. The insulating layer PAS1 is provided to cover the insulating layer UC and the signal lines SL. The contact hole CH2 is provided in the insulating layer PAS2.

The semiconductor layer SCO is provided on the insulating layer UC and is provided at the bottom portion of the contact hole CH2. The electrode IT1 is brought into contact with the semiconductor layer SCO so as to cover the contact hole CH2. Let us suppose here that the taper angle of the sidewall of the contact hole CH2 made in the insulating layer PAS2 is set to 0.

The display device DSPr3 shown in FIG. 16 comprises a base BA1, an insulating layer UC, a semiconductor layer SCO, an insulating layer GI, signal lines SL, an insulating layer PAS1, an insulating layer PAS2, and an electrode IT1. The base BA1, the insulating layer UC, the insulating layer GI, the insulating layer PAS1, and the insulating layer PAS2 are stacked into a multilayer in this order along the third direction Z. The signal lines SL are provided on the insulating layer PAS1. The insulating layer PAS2 is provided to cover the insulating layer PAS1 and the signal lines SL. The contact hole CH2 is provided in the insulating layer GI, the insulating layer PAS1, and the insulating layer PAS2.

The semiconductor layer SCOR is provided on the insulating layer UC and is provided at the bottom surface of the contact hole CH2. The electrode IT1 is in brought into contact with the semiconductor layer SCOR so as to cover the contact hole CH2. Let us suppose that the taper angle of the sidewall of the contact hole CH2 made in the insulating layer GI, the insulating layer PAS1, and the insulating layer PAS2 is set to θr.

The contact hole CH2 of Embodiment 2 (see FIG. 15) is provided only in the insulating layer PAS2, whereas the contact hole CH2 of Comparative Example 3 (see FIG. 16) is provided in the insulating layer GI, insulating layer PAS1, and insulating layer PAS2. When the taper angle θ and taper angle θr are equal to each other (θ=θr), the contact hole CH2 of Comparative Example 3 is shorter in distance from the sidewall of the contact hole CH2 to one corresponding signal line SL by a distance that satisfies (thickness of insulating layer GI+thickness of insulating layer PAS1)÷tan θr, compared to the case of the contact hole CH2 of Embodiment 2. In other words, the contact hole CH2 of Embodiment 2 can increase the distance from the sidewall of the contact hole CH2 to the signal line SL by the distance that satisfies (thickness of insulating layer GI+thickness of insulating layer PAS1)÷tan θr. As described, in Embodiment 2, the distance is increased as explained above, and accordingly, the risk of occurrence of a short-circuiting between the signal line SL and the electrode IT1 and the breakage of wiring of the electrode IT1 due to high taper can be reduced.

### Configuration Example 1 of Embodiment 2

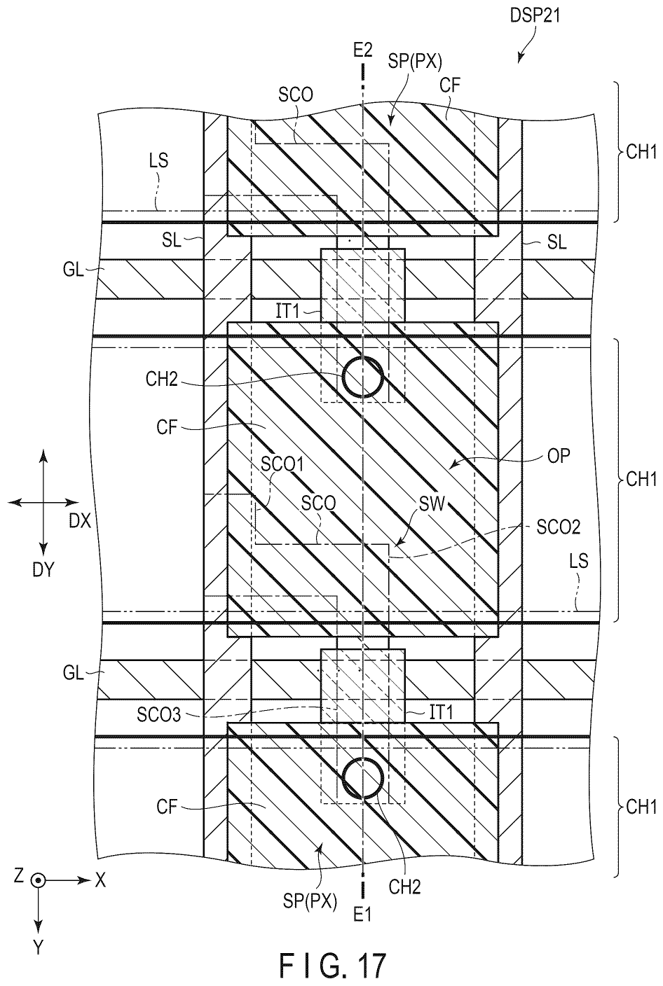

FIG. 17 is a plan view showing another configuration example of the display device in Embodiment 2. In the configuration example shown in FIG. 17, the color filters are provided on the array substrate side as shown in FIG. 5, as compared to the configuration example shown in FIG. 11.

In the display device DSP21 shown in FIG. 17, color filters CF are provided to overlap the aperture regions OP of the subpixels SP (pixels PX), respectively. The color filters CF have a rectangular shape in plan view. Of the sides of the rectangle, those sides which are parallel to the second direction Y overlap each respective adjacent pair of signal lines SL. Of the sides of the rectangle, those parallel to the first direction X are disposed between the scanning line GL and the light shielding layer LS.

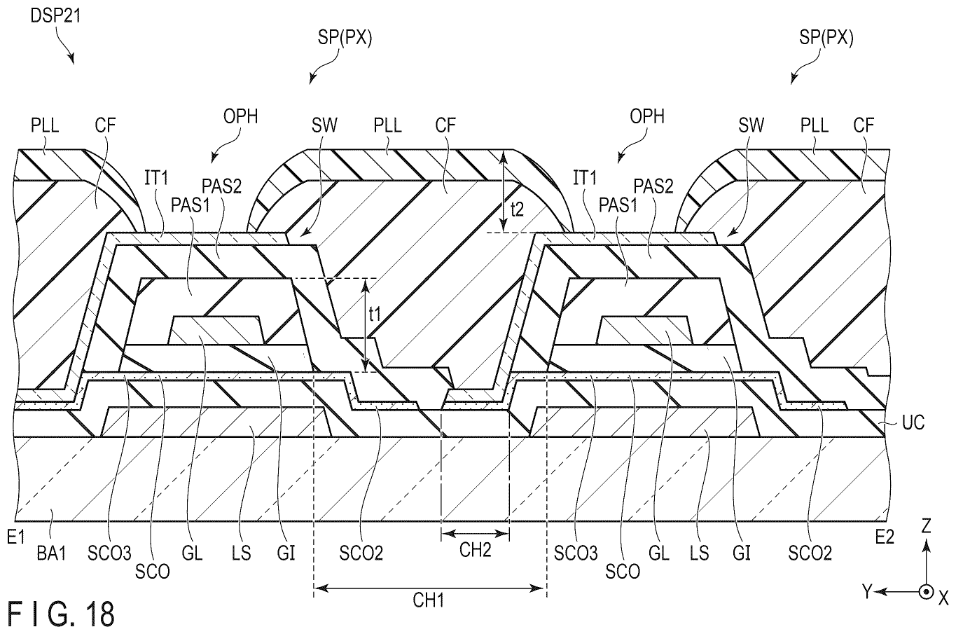

FIG. 18 is a cross-sectional view showing a cross-sectional configuration of the display device taken along the line E1-E2 shown in FIG. 17. FIG. 18 shows the cross-sectional configuration of two subpixels SP (pixel PX) aligned along a direction parallel to the second direction Y.

A light-shielding layer LS is provided on the base BA1. An insulating layer UC is provided to cover the base BA1 and the light-shielding layer LS. A semiconductor layer SCO is provided on the insulating layer UC. An insulating layer GI is provided on the semiconductor layer SCO. The insulating layer GI does not cover the entire semiconductor layer SCO, and a part of the semiconductor layer SCO is exposed from the insulating layer GI.

The semiconductor layer SCO shown in FIG. 18 includes a part of the third portion SCO3 and a part of the second portion SCO2. The third portion SCO3 is located on the left side of the page in FIG. 18, and the second portion SCO2 is located on the right side of the page. The above-mentioned part of the semiconductor layer SCO, that is exposed from the insulating layer GI is the part on the right-hand side of the third portion SCO3 and the part on the left-hand side of the second portion SCO2.

Each scanning lines GL is provided above the respective semiconductor layer SCO with the respective insulating layer GI interposed therebetween. An insulating layer PAS1 is provided to cover the insulating layer GI and the scanning line GL. The insulating layer PAS1 is not brought into contact with the semiconductor layer SCO.

The contact hole CH1 is formed in the insulating layer PAS1 and the insulating layer GI, so as to extend in a direction parallel to the first direction X. In FIG. 18, the contact hole CH1 is provided between the edge portions of the insulating layers GI of each adjacent pair of subpixels SP.

Each insulating layer PAS2 is provided so as to cover the respective insulating layer PAS1 and a part of the respective exposed semiconductor layer SCO. The insulating layer PAS2 covers the part of the second portion SCO2 of the semiconductor layer SCO at the right-hand edge of the page. On the other hand, the insulating layer PAS2 does not cover the left-hand edge portion of the third portion SCO3 of the semiconductor layer SCO, and a contact hole CH2 is formed in that part.

An electrode IT1 is provided on the respective insulating layer PAS2. The electrode IT1 extends from the region on the respective scanning line GL up to the second portion SCO2. The electrode IT1 is in contact with the third portion SCO3 of the semiconductor layer SCO in the respective contact hole CH2.

A color filter CF is provided on the respective insulating layer PAS2 and the respective electrode IT1. The color filter CF is provided independently for each subpixel SP.

An insulating layer PLL is provided on the color filter CF. Above each scanning line GL, an aperture region OPH, in which the color filter CF or the insulating layer PLL is provided, is located.

Here, the distance from the boundary between the semiconductor layer SCO and the insulating layer GI along the third direction Z to the boundary between the insulating layer PAS1 and the insulating layer PAS2 is defined as a thickness t1. The distance from the boundary between the electrode IT1 and the color filter CF along the third direction Z to the surface of the insulating layer PLL is defined as a thickness t2.

When the thickness of the color filter CF is increased, color reproduction is improved. But, there are restrictions on increasing the thickness due to manufacturing methods. More specifically, there are restrictions on the thickness t2 due to manufacturing methods.

In the display device DSP21 shown in this configuration example, each contact hole CH1 is provided over subpixel SP. With this configuration, it is possible to increase the thickness of the color filter CF by the thickness t1 without changing the thickness t2.

According to this configuration example, the effect of improving the color reproduction can be obtained in addition to the effects described in Embodiments 1 and 2 provided above.

This configuration example exhibits advantageous effects similar to those of Embodiments 1 and 2 provided above.

In this disclosure, the substrate SUB1 and substrate SUB2 are also referred to as a first substrate and a second substrate, respectively. The polarizer PL1 and polarizer PL2 are also referred to as a first polarizer and a second polarizer, respectively.

In this disclosure, the insulating layer GI, insulating layer PAS1, and insulating layer PLL shown in FIG. 8 are also referred to as a first insulating layer, a second insulating layer, and a third insulating layer, respectively. The contact hole CH1 and aperture region OPH are also referred to as a first contact hole and an aperture region, respectively.

In this disclosure, the insulating layer GI, the insulating layer PAS1, the insulating layer PAS2, and the insulating layer PLL shown in FIG. 10 are also referred to as a first insulating layer, a second insulating layer, a third insulating layer, and a fourth insulating layer, respectively. The contact hole CH1 and the contact hole CH2 and the aperture region OPH are also referred to as a first contact hole, a second contact hole, and an aperture region, respectively. The electrode IT1 is also referred to as a transparent electrode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a first substrate;
a second substrate; and
a liquid crystal layer disposed between the first substrate and the second substrate,
wherein
the first substrate comprises:
a plurality of scanning lines extending along a first direction;
a plurality of signal lines extending along a second direction intersecting the first direction;
a plurality of pixels each provided at an intersection of a respective one of the plurality of scanning lines and a respective one of the plurality of signal lines, and
a plurality of switching elements provided respectively in the plurality of pixels,
each of the plurality of switching elements comprises:
a semiconductor layer;
one scanning line of the plurality of scanning lines provided on the semiconductor layer;
one signal line of the plurality of signal lines, provided in contact with a first portion of the semiconductor layer;
a first insulating layer disposed between a third portion of the semiconductor layer and the one scanning line;
a second insulating layer covering the first insulating layer and the one scanning line; and
a first contact hole provided in the first insulating layer and the second insulating layer, and reaching the first portion of the semiconductor layer, and
the one signal line is in contact with the first portion of the semiconductor layer via the first contact hole, and
the first contact hole is provided across the plurality of pixels and has a rectangular shape in plan view.

2. The display device according to claim 1, wherein
the semiconductor layer is formed of polycrystalline silicon.

3. The display device according to claim 1, further comprising:
a drain electrode in contact with the third portion of the semiconductor layer;
a third insulating layer provided to cover the signal line, the drain electrode, and the semiconductor layer;
an aperture region formed in the third insulating layer and located above the scanning line.

4. The display device according to claim 1, wherein
the third portion of the semiconductor layer intersects the scanning line in parallel with the one signal line,
the semiconductor layer includes a second portion which connects the first portion and the third portion to each other and is parallel to the scanning line, and
the second portion is located within the first contact hole of the rectangular shape.

5. A display device comprising:
a first substrate;
a second substrate; and
a liquid crystal layer disposed between the first substrate and the second substrate,
wherein
the first substrate comprises:
a plurality of scanning lines extending along a first direction;
a plurality of signal lines extending along a second direction intersecting the first direction;
a plurality of pixels each provided at an intersection of a respective one of the plurality of scanning lines and a respective one of the plurality of signal lines, and
a plurality of switching elements provided respectively in the plurality of pixels,
each of the plurality of switching elements comprises:
a semiconductor layer;
one scanning line of the plurality of scanning lines provided on the semiconductor layer;
one signal line of the plurality of signal lines, provided in contact with a first portion of the semiconductor layer;
a first insulating layer disposed between a third portion of the semiconductor layer and the one scanning line;
a second insulating layer covering the first insulating layer and the one scanning line;
a first contact hole provided in the first insulating layer and the second insulating layer, and reaching a first portion of the semiconductor layer;
a third insulating layer provided to cover the second insulating layer, the first portion of the semiconductor layer, and the one signal line; and
a second contact hole provided in the first insulating layer, the second insulating layer, and the third insulating layer, and
the one signal line is in contact with the first portion of the semiconductor layer via the first contact hole, and
the first contact hole is provided across the plurality of pixels so as to pass through the plurality of signal lines, and has a rectangular shape in plan view.

6. The display device according to claim 5, wherein
the semiconductor layer is formed of an oxide semiconductor.

7. The display device according to claim 5, further comprising:
a transparent electrode in contact with the third portion of the semiconductor layer via the second contact hole;
a fourth insulating layer provided to cover the transparent electrode and the third insulating layer; and
an aperture region provided in the fourth insulating layer, and located above the scanning line.
